(19) United States
(12) Patent Application Publication
(10) Pub. No.: US 2010/0065917 A1
(43) Pub. Date: Mar. 18, 2010

(54) SEMICONDUCTOR DEVICE AND METHOD OF MANUFACTURING THE SAME

(76) Inventors: Atsushi Ohta, Yokohama-Shi (JP); Seiichi Iwasa, Oita-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/552,117

(22) Filed: Sep. 1, 2009

(30) Foreign Application Priority Data
Sep. 18, 2008 (JP) 2008-239266

(51) Int. Cl. H01L 27/092; H01L 21/8238

(52) U.S. Cl. 257/369; 438/218; 257/E27.062; 257/E21.632

(57) ABSTRACT

A semiconductor device having a double-gate structure has: a first fin layer; a first epitaxial growth layer formed on a surface of the first fin layer, and constituting a first source/drain diffusion layer, and containing the n-type impurity; a second fin layer; a second epitaxial growth layer formed on a surface of the second fin layer, constituting a second source/drain diffusion layer, and containing the p-type impurity; and a first isolation insulating film formed between the first epitaxial growth layer and the second epitaxial growth layer.

### CROSS-REFERENCE TO RELATED APPLICATION

This application is based upon and claims the benefit of priority from the prior Japanese Patent Application No. 2008-239266, filed on Sep. 18, 2008, the entire contents of which are incorporated herein by reference.

### BACKGROUND OF THE INVENTION

1. Field of the Invention

The present invention relates to a semiconductor device used in FinFET having a double-gate structure and a method of manufacturing the same.

2. Background Art

In recent years, application of a double-gate type FinFET to SRAM (Static Random Access Memory) in the post half-pitch 32-nm generation is studied. In the double-gate type FinFET, a β-ratio is easily controlled because of double-gate type FinFET's structure, and a variation in impurity is decreased (see Fu-Liang Yang, Haur-Ywh Chen, Fang-Cheng Chen, Yi-Lin Chan, Kuo-Nan Yang, Chih-Lian Chen, Hun-Jan Tao, Yang-Kyu Choi, Mong-Song Liang, and Cheing Hug “35 CMOS FinFETs”, IEEE, 2002, Symposium on VLSI Technology Digest of Technical Papers, p. 104-105, for example).

On the other hand, a source/drain width of FinFET in the half-pitch 32-nm generation is as small as about 20 nm. Therefore, a source/drain region of FinFET has a high parasitic resistance. The parasitic resistance causes degradation of FinFET performance.

For example, Japanese Patent Laid-Open No. 11-330238, discloses a technique, in which the source/drain region of FinFET is formed by an epitaxial growth to increase a volume of the source/drain region and an area of silicide, thereby reducing the parasitic resistance.

However, when a space between adjacent fin layers of FinFET is narrowed due to a finer process, adjacent epitaxial growth layers come into contact with each other to generate a leak current between the epitaxial growth layers. Therefore, possibly a product yield is lowered.

### SUMMARY OF THE INVENTION

According to one aspect of the present invention, there is provided: a semiconductor device having a double-gate structure, comprising:

a buried insulating film formed on a semiconductor substrate;

a first fin layer formed on the buried insulating film, being extended in a first direction, being made of a silicon or germanium single crystal, and containing an n-type impurity;

first gate insulators formed on first sidewalls of the first fin layer, the first sidewalls being perpendicular to a second direction, the second direction being orthogonal to the first direction;

a first gate electrode formed on the buried insulating film, being extended in the second direction, and being in contact with the first sidewalls with the first gate insulators interposed therebetween;

a first epitaxial growth layer formed on a surface of the first fin layer, constituting a first source/drain diffusion layer, and containing a n-type impurity;

a second fin layer formed on the buried insulating film, being extended in a first direction, being adjacent to the first fin layer in the second direction, being made of the silicon or germanium single crystal, and containing a p-type impurity;

second gate insulators formed on second sidewalls of the second fin layer, the second sidewalls being perpendicular to the second direction;

a second gate electrode formed on the buried insulating film, being extended in the second direction, and being in contact with the second sidewalls with the second gate insulators interposed therebetween;

a second epitaxial growth layer formed on a surface of the second fin layer, constituting a second source/drain diffusion layer, and containing a p-type impurity; and

a first isolation insulating film formed between the first epitaxial growth layer and the second epitaxial growth layer.

According to another aspect of the present invention, there is provided: a method of manufacturing a semiconductor device having a double-gate structure, comprising:

forming a plurality of mask films extended in a first direction on a semiconductor layer made of a silicon or germanium single crystal, the semiconductor layer being formed on a buried insulating film on a semiconductor substrate;

forming a first fin layer and a second fin layer by etching the semiconductor layer with the plurality of mask films as a mask, the first fin layer being extended in the first direction, the second fin layer being extended in the first direction and being adjacent to the first fin layer in a second direction orthogonal to the first direction;

forming first gate insulators on first sidewalls of the first fin layer, the first sidewalls being perpendicular to the second direction;

forming second gate insulators on second sidewalls of the second fin layer, the second sidewalls being perpendicular to the second direction;

forming a first gate electrode on the buried insulating film, the first gate electrode being extended in the second direction and being in contact with the first sidewalls with the first gate insulators interposed therebetween;

forming a second gate electrode on the buried insulating film, the second gate electrode being extended in the second direction and being in contact with the second sidewalls in the second direction of the second fin layer with the second gate insulators interposed therebetween;

forming a first isolation insulating film extended in the first direction between a first portion constituting a first source/drain diffusion layer of the first fin layer and a second portion constituting a second source/drain diffusion layer of the second fin layer;

forming a first epitaxial growth layer on a surface of the first portion by epitaxial growth;

forming a second epitaxial growth layer on a surface of the second portion by epitaxial growth;

implanting an n-type impurity into the first epitaxial growth layer and the first portion of the first fin layer; and

implanting a p-type impurity into the second epitaxial growth layer and the second portion of the second fin layer.

### BRIEF DESCRIPTION OF THE DRAWINGS

FIG. 1A is a plan view showing an example of a configuration of a semiconductor device 100 according to a first embodiment of the invention;

FIG. 1B is a sectional view taken on a line a-a of the semiconductor device 100 of FIG. 1A;

FIG. 1C is a sectional view taken on a line b-b of the semiconductor device 100 of FIG. 1A;

FIG. 2A is a process plan view for explaining the method of manufacturing the semiconductor device 100 according to the first embodiment of the invention;

FIG. 2B is a sectional view taken along a line a-a of the process of FIG. 2A;

FIG. 2C is a sectional view taken along a line b-b of the process of FIG. 2A;

FIG. 3A is a process plan view for explaining the method of manufacturing the semiconductor device 100 according to the first embodiment of the invention, is continuous from FIG. 2A;

FIG. 3B is a sectional view taken along a line a-a of the processes of FIG. 3A;

FIG. 3C is a sectional view taken along a line b-b of the process of FIG. 3A;

FIG. 4A is a process plan view for explaining the method of manufacturing the semiconductor device 100 according to the first embodiment of the invention, is continuous from FIG. 3A;

FIG. 4B is a sectional view taken along a line a-a of the processes of FIG. 4A;

FIG. 4C is a sectional view taken along a line b-b of the process of FIG. 4A;

FIG. 5A is a process plan view for explaining the method of manufacturing the semiconductor device 100 according to the first embodiment of the invention, is continuous from FIG. 4A;

FIG. 5B is a sectional view taken along a line a-a of the processes of FIG. 5A;

FIG. 5C is a sectional view taken along a line b-b of the process of FIG. 5A;

FIG. 6A is a process plan view for explaining the method of manufacturing the semiconductor device 100 according to the first embodiment of the invention, is continuous from FIG. 5A;

FIG. 6B is a sectional view taken along a line a-a of the processes of FIG. 6A;

FIG. 6C is a sectional view taken along a line b-b of the process of FIG. 6A;

FIG. 7A is a process plan view for explaining the method of manufacturing the semiconductor device 100 according to the first embodiment of the invention, is continuous from FIG. 6A;

FIG. 7B is a sectional view taken along a line a-a of the processes of FIG. 7A;

FIG. 7C is a sectional view taken along a line b-b of the process of FIG. 7A;

FIG. 8A is a process plan view for explaining the method of manufacturing the semiconductor device 100 according to the first embodiment of the invention, is continuous from FIG. 7A;

FIG. 8B is a sectional view taken along a line a-a of the processes of FIG. 8A;

FIG. 8C is a sectional view taken along a line b-b of the process of FIG. 8A;

FIG. 9A is a process plan view for explaining the method of manufacturing the semiconductor device 100 according to the first embodiment of the invention, is continuous from FIG. 8A;

FIG. 9B is a sectional view taken along a line a-a of the processes of FIG. 9A;

FIG. 9C is a sectional view taken along a line b-b of the process of FIG. 9A;

FIG. 10A is a process plan view for explaining the method of manufacturing the semiconductor device 100 according to the first embodiment of the invention, is continuous from FIG. 9A;

FIG. 10B is a sectional view taken along a line a-a of the processes of FIG. 10A; and

FIG. 10C is a sectional view taken along a line b-b of the process of FIG. 10A.

### DETAILED DESCRIPTION

The present invention has been made in view of these circumstances, and an object thereof is to provide a semiconductor device having a double-gate structure in which the product yield can be improved.

Embodiments according to the present invention will be described below with reference to the drawings.

### First Embodiment

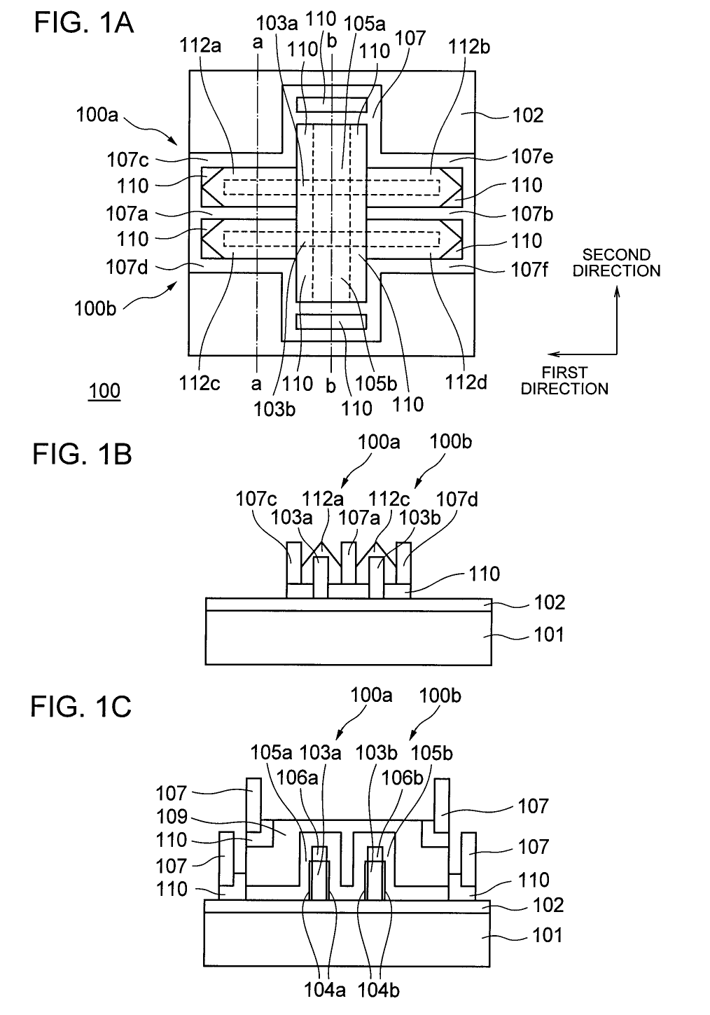

FIG. 1A is a plan view showing an example of a configuration of a semiconductor device 100 according to a first embodiment of the invention. FIG. 1B is a sectional view taken on a line a-a of the semiconductor device 100 of FIG. 1A. FIG. 1C is a sectional view taken on a line b-b of the semiconductor device 100 of FIG. 1A.

Referring to FIGS. 1A to 1C, the semiconductor device 100 that is of a double-gate type FinFET includes n-MOSFET 100a and p-MOSFET 100b.

That is, the semiconductor device 100 includes a semiconductor substrate 101, a buried insulating film 102, a first fin layer 103a, a second fin layer 103b, a first gate insulator 104a, a second gate insulator 104b, a first gate electrode 105a, a second gate electrode 105b, insulating films 106a and 106b, first isolation insulating films 107a and 107b, second isolation insulating films 107c and 107e, third isolation insulating films 107d and 107f, insulating films 109 and 110, first epitaxial growth layers 112a and 112b, and second epitaxial growth layers 112c and 112d.

The buried insulating film 102 is formed on the semiconductor substrate 101.

The first fin layer 103a is formed on the buried insulating film 102 and is extended in a first direction X. The first fin layer 103a is made of a silicon or germanium single crystal. In the first fin layer 103a, a portion in which the source/drain diffusion layer is formed contains an n-type impurity.

The first gate insulators 104a are selectively formed on sidewalls of the first fin layer 103a. The sidewalls are perpendicular to a second direction Y. The second direction Y is orthogonal to the first direction X.

The first gate electrode 105a is formed on the buried insulating film 102 and is extended in the second direction Y. The first gate electrode 105a is in contact with the sidewalls of the first fin layer 103a with the first gate insulators 104a interposed therebetween.

The first epitaxial growth layers 112a and 112b are selectively formed on a surface of the first fin layer 103a. The first epitaxial growth layers 112a and 112b constitute the source/drain diffusion layer, and the first epitaxial growth layers 112a and 112b contain the n-type impurity.

The second fin layer 103b is formed on the buried insulating film 102 and is extended in the first direction X. The second fin layer 103b is adjacent to the first fin layer 103a in the second direction Y. The second fin layer 103b is made of a silicon or germanium single crystal. In the second fin layer 103b, a portion in which the source/drain diffusion layer is formed contains a p-type impurity.

The second gate insulators 104b are selectively formed on sidewalls of the second fin layer 103b. The sidewalls are perpendicular to the second direction Y.

The second gate electrode 105b is formed on the buried insulating film 102 and is extended in the second direction Y. The second gate electrode 105b is in contact with sidewalls of the second fin layer 103b with the second gate insulator 104b interposed therebetween.

In the first embodiment, the first gate electrode 105a and the second gate electrode 105b are electrically connected to each other. However, it is not necessary to electrically connect the first gate electrode 105a and the second gate electrode 105b.

The second epitaxial growth layers 112c and 112d are selectively formed on the surface of the second fin layer 103b. The second epitaxial growth layers 112c and 112d constitute the source/drain diffusion layer and contain the p-type impurity.

For example, the first epitaxial growth layers 112a and 112b and the second epitaxial growth layers 112c and 112d are made of single-crystal silicon, single-crystal silicon-germanium, or single-crystal silicon carbide.

The first isolation insulating film 107a and 107b are formed between the first epitaxial growth layers 112a and 112b and the second epitaxial growth layers 112c and 112d, respectively.

The first isolation insulating films 107a and 107b are formed before the first epitaxial growth layers 112a and 112b and the second epitaxial growth layers 112c and 112d are formed as described later.

The second isolation insulating films 107c and 107e are formed on the buried insulating film 102 and are extended in the first direction X. The first fin layer 103a is located between the first isolation insulating films 107a, 107b and the second isolation insulating films 107c, 107e, respectively.

The second isolation insulating films 107c and 107e are formed before the first epitaxial growth layers 112a and 112b are formed as described later.

The third isolation insulating films 107d and 107f are formed on the buried insulating film 102 and are extended in the first direction X. The second fin layer 103b is located between the first isolation insulating films 107a, 107b and the third isolation insulating films 107d, 107f, respectively.

The third isolation insulating films 107d and 107f are formed before the second epitaxial growth layers 112c and 112d are formed as described later.

The first and second epitaxial growth layers 112a to 112d are insulated from the first and second gate electrodes 105a and 105b by the insulating film 110 that acts as a gate sidewall insulating film.

A sectional area of the source/drain can be enlarged by controlling sizes (sectional areas) of the first and second epitaxial growth layers 112a to 112d. That is, the parasitic resistance of the source/drain can drastically be reduced.

At this point, because the first isolation insulating films 107a and 107b are formed between the first and second fin layers 103a and 103b, the epitaxial growth is obstructed by the first isolation insulating films 107a and 107b. That is, a short circuit between the first and second epitaxial growth layers 112a to 112d can be prevented.

As described later, thicknesses of the first and second epitaxial growth layers 112a to 112d can be controlled by a thickness of the oxide film 110. Therefore, characteristics can be equalized among FinFETs having the different gap between the adjacent fin layers.

Accordingly, the short circuit between the epitaxial growth layers is prevented by forming the insulating film between the adjacent fin layers, so that the decrease in product yield can be suppressed.

In the first embodiment, the insulating films 106a and 106b are formed so as to act as a gate forming hard mask as described later. Therefore, the semiconductor device 100 has the double-gate structure. Alternatively, the insulating films 106a and 106b are peeled off after the gate is formed, and the insulating film acting as the gate insulator may be formed on the first and second fin layers 103a and 103b (portion in which the insulating films 106a and 106b are formed).

Here, an operation of the semiconductor device 100 having the above configurations will briefly be described.

In n-MOSFET 100a, a control voltage is applied to the first gate electrode 105a to form a channel between side surfaces in the first fin layer 103a sandwiched by the first gate electrode 105a. The current passed through the source/drain diffusion layer including the first fin layer 103a and first epitaxial growth layers 112a and 112b can be controlled by controlling the control voltage.

In p-MOSFET 100b, a control voltage is applied to the second gate electrode 105b to form a channel between side surfaces in the second fin layer 103b sandwiched by the second gate electrode 105b. The current passed through the source/drain diffusion layer including the second fin layer 103b and second epitaxial growth layers 112c and 112d can be controlled by controlling the control voltage.

Next, an example of a method of manufacturing the semiconductor device 100 having the double-gate structure will be described below.

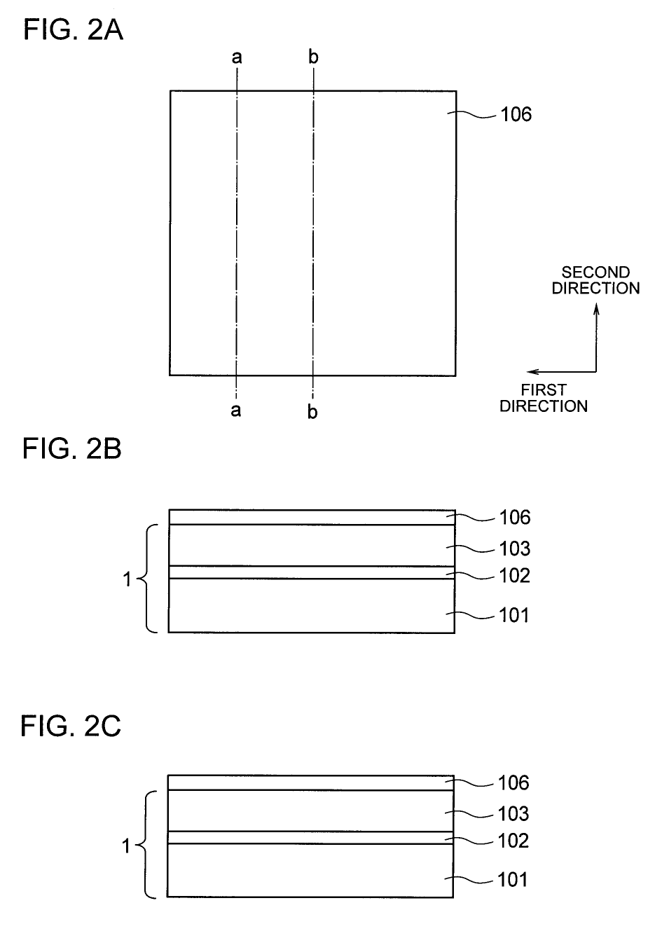

FIGS. 2A to 10A are process plan views for explaining the method of manufacturing the semiconductor device 100 according to the first embodiment of the invention. FIGS. 2B to 10B are sectional views taken along lines a-a of the processes of FIGS. 2A to 10A. FIGS. 2C to 10C are sectional views taken along lines b-b of the processes of FIGS. 2A to 10A.

First, the insulating film (for example, silicon nitride film) 106 constituting a mask film is formed on the semiconductor layer 103 made of the silicon or germanium single crystal by CVD (Chemical Vapor Deposition). The semiconductor layer 103 is formed on the buried insulating film 102 on the semiconductor substrate 101 (FIGS. 2A to 2C). That is, the insulating film 106 is formed on an SOI substrate 1.

Next, plural photoresists (not shown) extended in the first direction X are formed. The insulating film 106 is etched by RIE (Reactive Ion Etching) with the photoresists as the mask. Therefore, the plural insulating films 106a and 106b constituting the plural mask films extended in the first direction are formed on the semiconductor layer 103.

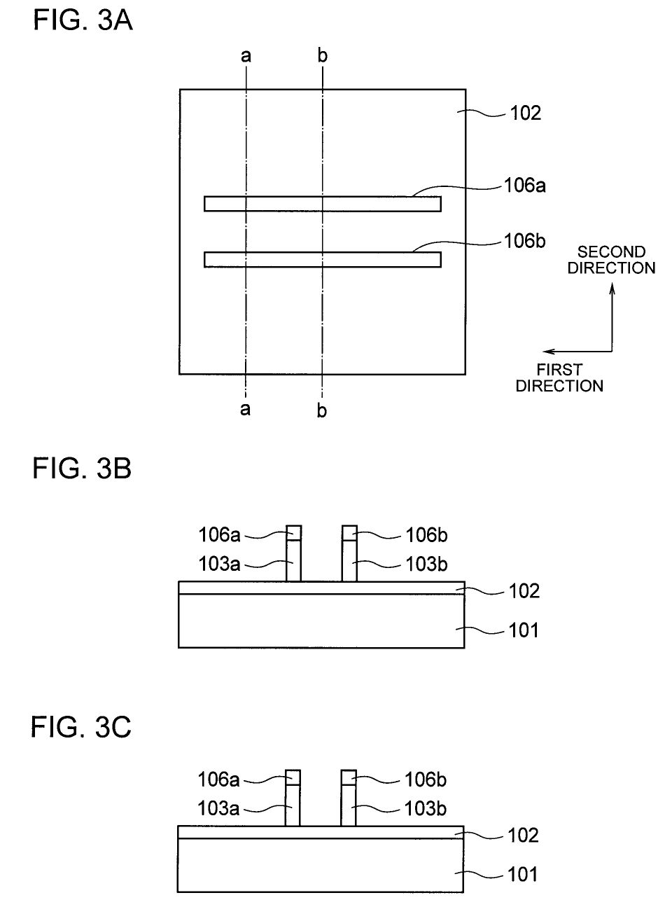

Further, the semiconductor layer 103 is selectively etched with the plural insulating films 106a and 106b as the hard mask, thereby forming the first fin layer 103a and the second fin layer 103b. The first fin layer 103a is extended in the first direction X. The second fin layer 103b is extended in the first direction X and adjacent to the first fin layer 103a in the second direction Y orthogonal to the first direction X (FIGS. 3A to 3C).

Then, the first gate insulators 104a are selectively (in a neighborhood of a region corresponding to the channel region) formed on the sidewalls of the first fin layer 103a by thermal oxidation. The sidewalls of the first fin layer 103a are perpendicular to the second direction Y. Furthermore, the second gate insulators 104b are selectively (in a neighborhood of a region corresponding to the channel region) formed on the sidewalls of the second fin layer 103b by the thermal oxidation. The sidewalls of the second fin layer 103b are perpendicular to the second direction Y.

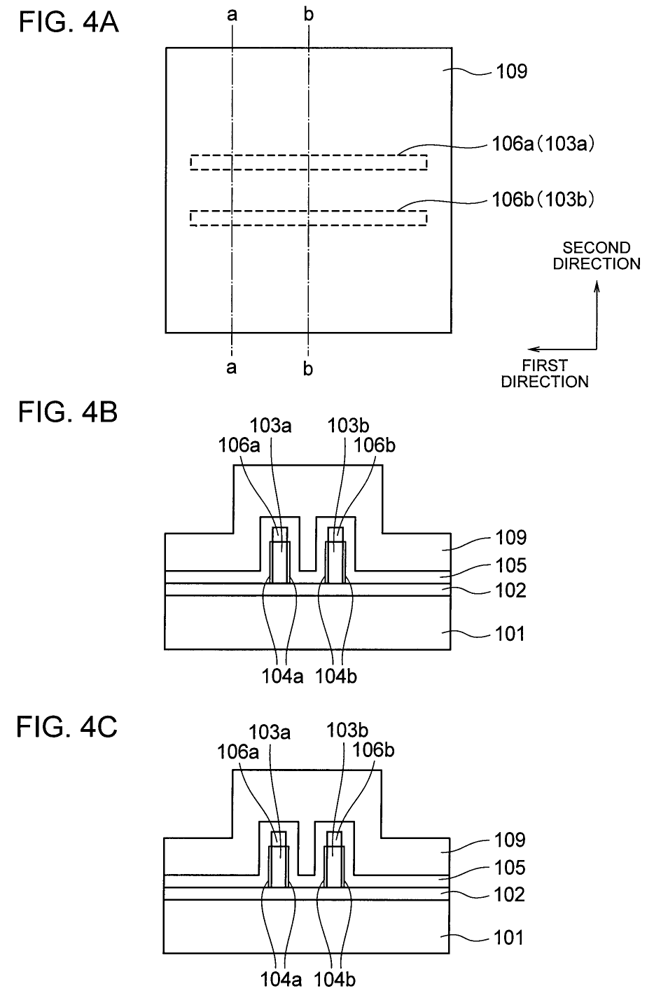

Thereafter, the electrode material layer (for example, polysilicon) 105 constituting a gate electrode is deposited in the whole surface of the semiconductor substrate 101, and the insulating film (for example, silicon nitride film) 109 is deposited on the electrode material layer 105 (FIGS. 4A to 4C).

Then a resist (not shown) is patterned such that the gate electrodes are formed in central portions of the first and second fin layers 103a and 103b. The electrode material layer 105 is selectively etched by, for example, RIE with the resist as the mask.

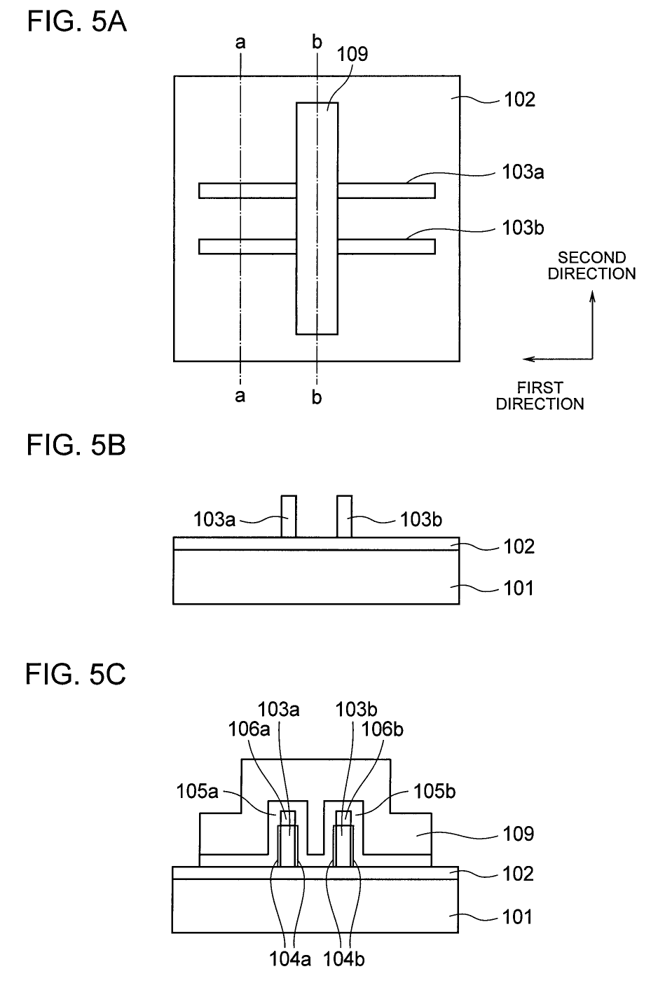

Therefore, the first gate electrode 105a and the second gate electrode 105b are formed. The first gate electrode 105a is formed on the buried insulating film 102, is extended in the second direction Y, and is in contact with the sidewalls of the first fin layer 103a with the first gate insulators 104a interposed therebetween. Furthermore, the second gate electrode 105b is formed on the buried insulating film 102, is extended in the second direction Y, and is in contact with sidewalls of the second fin layer 103b with the second gate insulator 104b interposed therebetween (FIGS. 5A to 5C). As described above, the first gate electrode 105a and the second gate electrode 105b are electrically connected to each other.

Thus, in the first embodiment, the first gate electrode 105a and the second gate electrode 105b are simultaneously formed. Alternatively, the first and second gate electrodes 105a and 105b may separately be formed.

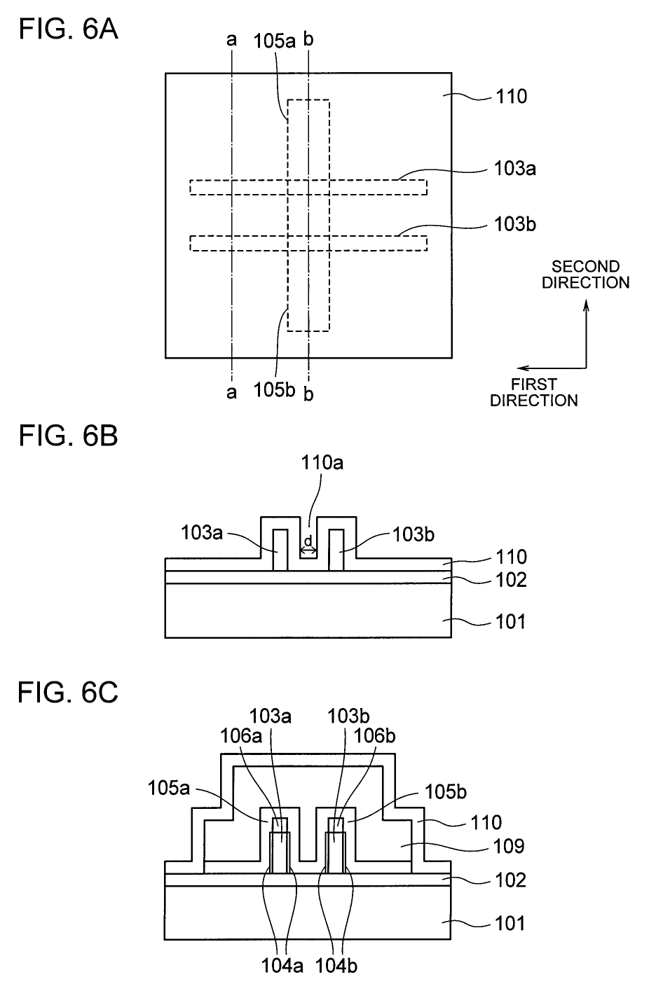

Then, in order to form the gate sidewalls of the first and second gate electrodes 105a and 105b, the insulating film (for example, silicon nitride film) 110 is deposited in the whole surface of the semiconductor substrate 101 by, for example, CVD (FIGS. 6A to 6C).

A grave-shaped recess 110a extended in the first direction X is formed between the first and second fin layers 103a and 103b (FIG. 6B). The insulating film 110 is formed on the surfaces of the first and second fin layers 103a and 103b. A width d in the recess 110a can be controlled by controlling the thickness of the insulating film 110.

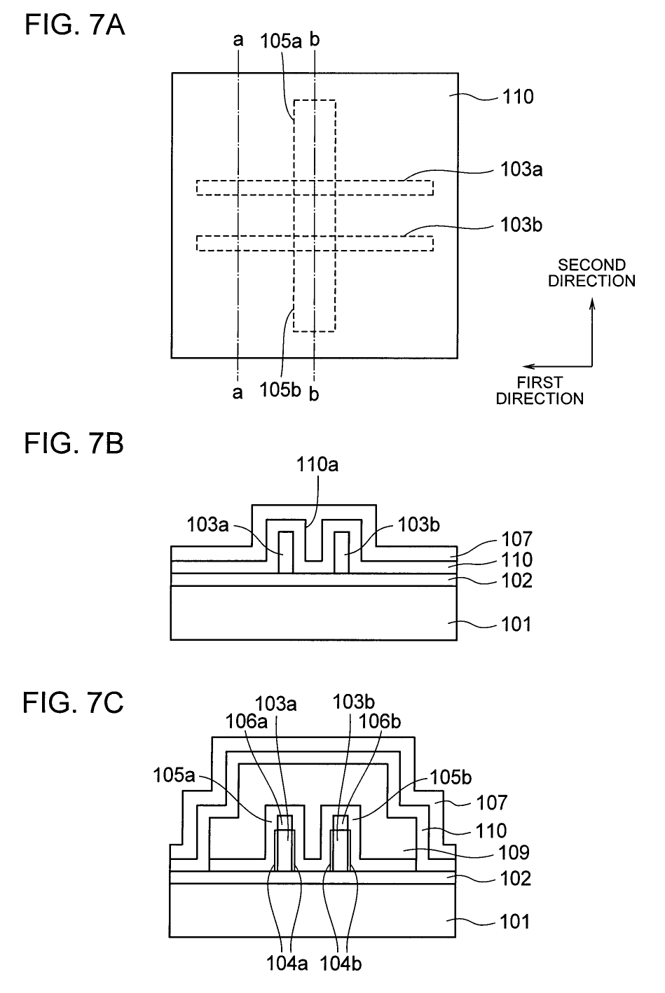

Next, the insulating film 107 such as a silicon oxide film is deposited in the whole surface of the semiconductor substrate 101 (FIGS. 7A to 7C). Therefore, the recess 110a is filled with the insulating film 107 (FIG. 7B).

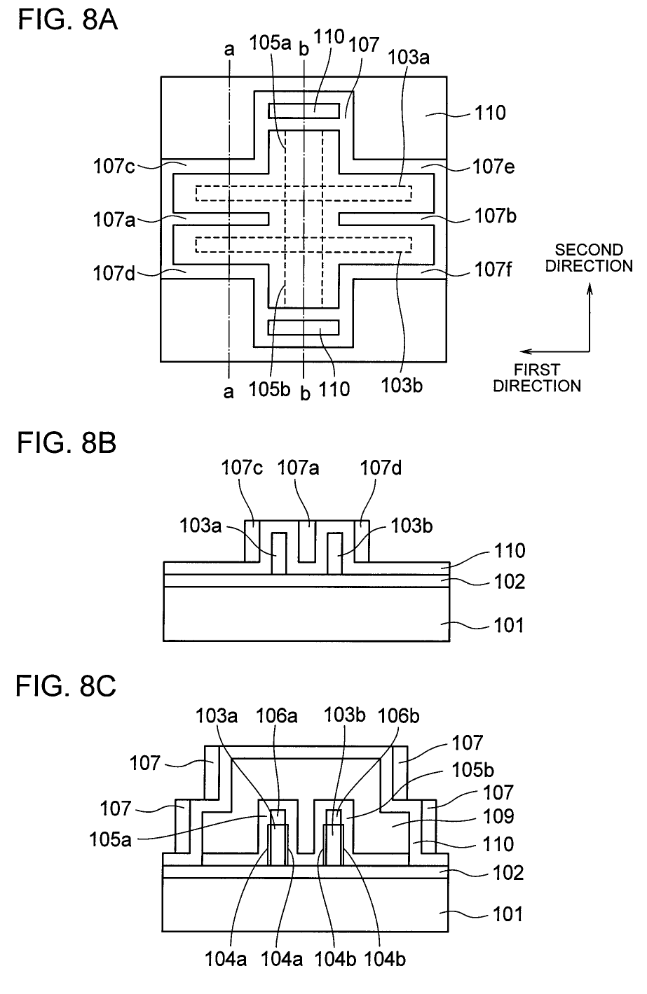

Then, etch back is performed to the insulating film 107 by, for example, RIE (FIGS. 8A to 8C).

Therefore, the first isolation insulating films 107a and 107b extended in the first direction X are formed between a portion constituting the source/drain diffusion layer of the first fin layer 103a and a portion constituting the source/drain diffusion layer of the second fin layer 103b. Further, the second isolation insulating films 107c and 107e extended in the first direction X are formed on the buried insulating film 102 with the insulating film 110 interposed therebetween. The first fin layer 103a is located between the first isolation insulating films 107a, 107b and the second isolation insulating films 107c, 107e, respectively. Further, the second isolation insulating film 107d and 107f extended in the first direction X are formed on the buried insulating film 102 with the insulating film 110 interposed therebetween. The second fin layer 103b is located between the first isolation insulating films 107a, 107b and the second isolation insulating film 107d, 107f, respectively.

As described above, the width d (FIG. 6B) in the recess 110a can be controlled by controlling the thickness of the insulating film 110. That is, the widths of the first isolation insulating films 107a and 107b can be controlled by controlling the thickness of the insulating film 110.

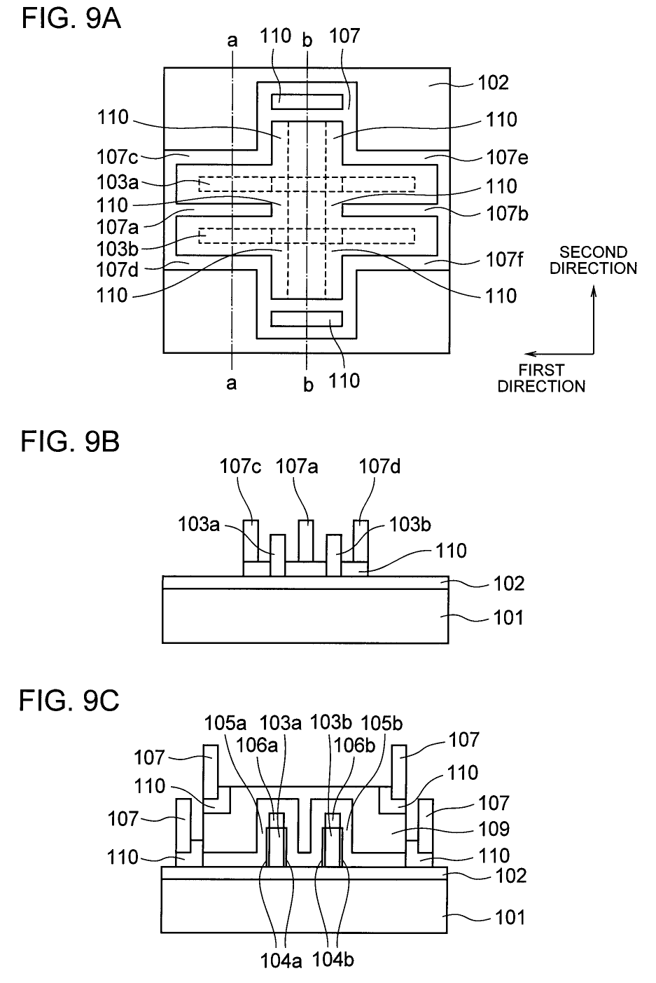

Then, etch back is performed to the insulating film 110 and the insulating film 109 by, for example, RIE (FIGS. 9A to 9C).

At this point, the insulating film 110 can be left only in the side surfaces of the first and second gate electrodes 105a and 105b by adjusting an amount of etch back performed to the insulating films 110 and 109. That is, the gate sidewalls of the first and second gate electrodes 105a and 105b can be formed.

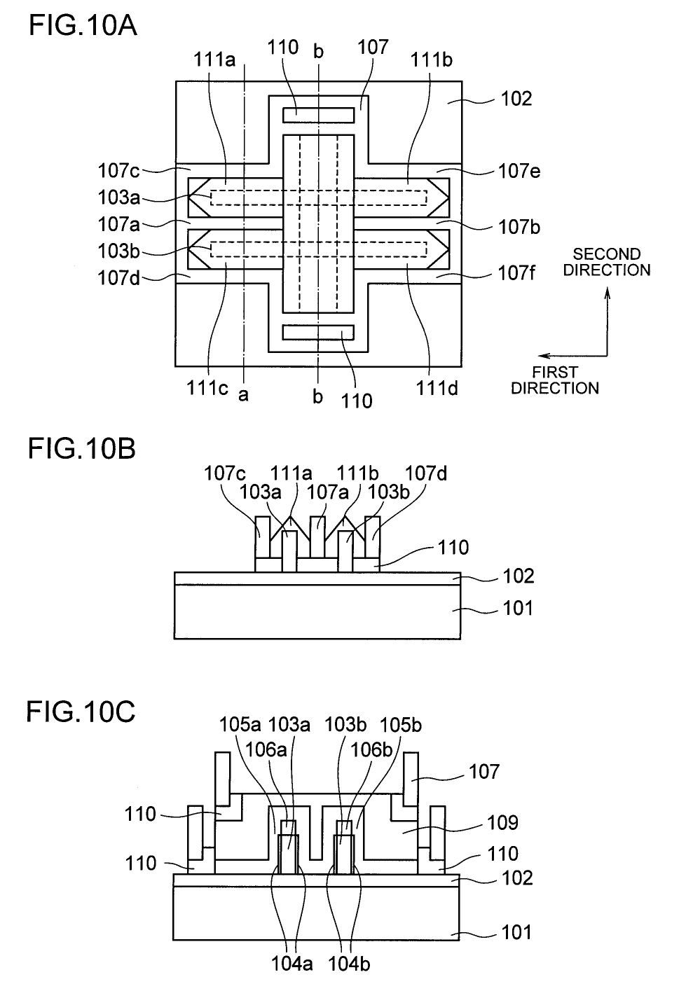

Next, the first epitaxial growth layers 111a and 111b are formed by the epitaxial growth on the surface of the portion constituting the source/drain diffusion layer of the first fin layer 103a. Further, the second epitaxial growth layers 111c and 111d are formed by the epitaxial growth on the surface of the portion constituting the source/drain diffusion layer of the second fin layer 103b (FIGS. 10A to 10C).

At this point, conventionally, the setting of the deposition condition is required so as not to short-circuit the adjacent epitaxial growth layers. On the other hand, in the first embodiment, because the first isolation insulating films 107a and 107b act as a stopper, the short circuit is suppressed. Therefore, the product yield can be improved. Additionally, it is not necessary to consider the setting of the deposition condition to prevent the short circuit. That is, the design of the semiconductor device 100 is facilitated.

In the same deposition condition, the thicknesses of the first and second epitaxial growth layers 111a to 111d are controlled by the widths of the first isolation insulating films 107a and 107b. At this point, as described above, the widths of the first isolation insulating films 107a and 107b can be controlled by controlling the thickness of the insulating film 110.

That is, the thicknesses of the first and second epitaxial growth layers 111a to 111d are controlled by the thickness of the insulating film 110. Therefore, the characteristics can be equalized among FinFETs having the different gap between the adjacent fin layers.

Next, the n-type impurity is implanted into the portion constituting the source/drain diffusion layer of the first fin layer 103a and the first epitaxial growth layers 111a and 111b by ion implantation with a resist (not shown) as the mask. Further, the p-type impurity is implanted into the portion constituting the source/drain diffusion layer of the second fin layer 103b and the second epitaxial growth layers 111c and 111d by the ion implantation with a resist (not shown) as the mask.

Therefore, n-MOSFET 100a and p-MOSFET 100b are formed (FIGS. 1A to 1C).

The order in which the impurities are implanted may be reversed.

The semiconductor device 100 having the double-gate structure that can improve the product yield is formed through the above-described processes.

As described above, in the semiconductor device according to the first embodiment, the product yield can be improved.

What is claimed is:

1. A semiconductor device having a double-gate structure, comprising:
a buried insulating film formed on a semiconductor substrate;
a first fin layer formed on the buried insulating film, being extended in a first direction, being made of a silicon or germanium single crystal, and containing an n-type impurity;
first gate insulators formed on first sidewalls of the first fin layer, the first sidewalls being perpendicular to a second direction, the second direction being orthogonal to the first direction;
a first gate electrode formed on the buried insulating film, being extended in the second direction, and being in contact with the first sidewalls with the first gate insulators interposed therebetween;
a first epitaxial growth layer formed on a surface of the first fin layer, constituting a first source/drain diffusion layer, and containing a n-type impurity;
a second fin layer formed on the buried insulating film, being extended in a first direction, being adjacent to the first fin layer in the second direction, being made of the silicon or germanium single crystal, and containing a p-type impurity;
second gate insulators formed on second sidewalls of the second fin layer, the second sidewalls being perpendicular to the second direction;
a second gate electrode formed on the buried insulating film, being extended in the second direction, and being in contact with the second sidewalls with the second gate insulators interposed therebetween;
a second epitaxial growth layer formed on a surface of the second fin layer, constituting a second source/drain diffusion layer, and containing a p-type impurity; and
a first isolation insulating film formed between the first epitaxial growth layer and the second epitaxial growth layer.

2. The semiconductor device according to claim 1, wherein the first gate electrode and the second gate electrode are electrically connected to each other.

3. The semiconductor device according to claim 1, wherein the first epitaxial growth layer and the second epitaxial growth layer are made of single-crystal silicon, single-crystal silicon-germanium, or single-crystal silicon carbide.

4. The semiconductor device according to claim 1, wherein the first isolation insulating film is formed before the first epitaxial growth layer and the second epitaxial growth layer are formed.

5. The semiconductor device according to claim 1, further comprising:
a second isolation insulating film formed on the buried insulating film and being extended in the first direction, the first fin layer being located between the first isolation insulating film and the second isolation insulating film; and
a third isolation insulating film formed on the buried insulating film and being extended in the first direction, the second fin layer being located between the first isolation insulating film and the third isolation insulating film.

6. The semiconductor device according to claim 1, wherein the first gate electrode and the second gate electrode are made of polysilicon.

7. A method of manufacturing a semiconductor device having a double-gate structure, comprising:
forming a plurality of mask films extended in a first direction on a semiconductor layer made of a silicon or germanium single crystal, the semiconductor layer being formed on a buried insulating film on a semiconductor substrate;
forming a first fin layer and a second fin layer by etching the semiconductor layer with the plurality of mask films as a mask, the first fin layer being extended in the first direction, the second fin layer being extended in the first direction and being adjacent to the first fin layer in a second direction orthogonal to the first direction;
forming first gate insulators on first sidewalls of the first fin layer, the first sidewalls being perpendicular to the second direction;
forming second gate insulators on second sidewalls of the second fin layer, the second sidewalls being perpendicular to the second direction;
forming a first gate electrode on the buried insulating film, the first gate electrode being extended in the second direction and being in contact with the first sidewalls with the first gate insulators interposed therebetween;
forming a second gate electrode on the buried insulating film, the second gate electrode being extended in the second direction and being in contact with the second sidewalls in the second direction of the second fin layer with the second gate insulators interposed therebetween;
forming a first isolation insulating film extended in the first direction between a first portion constituting a first source/drain diffusion layer of the first fin layer and a second portion constituting a second source/drain diffusion layer of the second fin layer;
forming a first epitaxial growth layer on a surface of the first portion by epitaxial growth;
forming a second epitaxial growth layer on a surface of the second portion by epitaxial growth;
implanting an n-type impurity into the first epitaxial growth layer and the first portion of the first fin layer; and
implanting a p-type impurity into the second epitaxial growth layer and the second portion of the second fin layer.

8. The method according to claim 7, wherein the first gate electrode and the second gate electrode are simultaneously formed.

9. The method of manufacturing a semiconductor device according to claim 7, further comprising:
forming a second isolation insulating film on the buried insulating film when the first isolation insulating film is formed, the second isolation insulating film being extended in the first direction, the first fin layer being located between the first isolation insulating film and the second isolation insulating film; and
forming a third isolation insulating film on the buried insulating film when the first isolation insulating film is formed, the third isolation insulating film being extended in the first direction, the second fin layer being located between the first isolation insulating film and the third isolation insulating film.

10. The method according to claim 7, wherein the first epitaxial growth layer and the second epitaxial growth layer are made of single-crystal silicon, single-crystal silicon-germanium, or single-crystal silicon carbide.

11. The method according to claim 7, wherein the first gate electrode and the second gate electrode are electrically connected to each other.

12. The method according to claim 7, wherein the first gate electrode and the second gate electrode are made of polysilicon.
